(19) United States
(12) Patent Application Publication
(10) Pub. No.: US 2012/0007604 A1
(43) Pub. Date: Jan. 12, 2012

(54) TRL Calibration Method for a Microwave Package And a Set of Standard Packages

(75) Inventors: Thierry Barbier, Guyancourt (FR); Daniel Caban-Chastas, Sevres (FR); Valérie Rananjason, Plaisir (FR); Gérard Tempez, Les Essarts Le Roi (FR)

(73) Assignee: THALES, Neuilly-sur-Seine (FR)

(21) Appl. No.: 12/996,552

(22) PCT Filed: Jun. 4, 2009
(86) PCT No.: PCT/EP2009/056855

§ 371 Date: Sep. 26, 2011

(30) Foreign Application Priority Data
Jun. 6, 2008 (FR) 0803172

(51) Int. Cl. G01R 35/00; G01R 27/04

(52) U.S. Cl. 324/601; 324/644

(57) ABSTRACT

A method of calibrating a test platform for microwave packages is provided. According to the invention, the conventional Thru, Reflect and Line standard patterns are replaced by microwave standard packages fulfilling similar functions, the test platform being adapted accordingly. The use of standard packages makes it possible to retain the same electrical interface between each of the packages and the test platform. The invention also relates to a method of determining an electrical length L_{C} of an etched line linking two microwave feeds of a microwave standard package. The standard package may be connected to the test platform. According to the invention, various electrical lengths of the test platform are measured so as to be able to deduce therefrom the electrical length L_{C} of the etched line of the standard package. The invention exhibits the advantage of obtaining the electrical length L_{C} by measurement rather than by modeling.

The present invention relates to a method of calibrating a test platform able to receive a microwave package. It is applied notably to microwave packages whose electrical interface with the printed circuit on which they are implanted is of the ball grid array type. The invention also relates to a set of microwave standard packages able to be connected to the test platform. The invention relates finally to a method of determining an electrical length of an etched line of a microwave standard package.

The main function of a microwave package is to protect from the exterior electromagnetic environment a microwave component that it encloses. For this purpose, the interior walls of the package may be covered with a conducting surface forming an earth, this earth generally being linked to the earth of the printed circuit on which the package is mounted. The other function of a microwave package is to protect the microwave component from the exterior physical environment, notably from moisture. For this purpose, the package may be closed in a hermetic manner, an inert gas, for example argon, being enclosed in the package.

A microwave package may be of pin grid array, land grid array or ball grid array type. The packages of pin grid array type, better known by the name “PGA packages”, comprise connection points embodied in the form of pins disposed on the lower face of the package along concentric perimeters. The packages of land grid array type, better known by the name “LGA packages”, comprise connection points embodied in the form of lands disposed on the lower face of the package in a matrix-like array or on the perimeter of the package. The packages of ball grid array type, better known by the name “BGA” packages, comprise connection balls disposed in a matrix-like array on the lower surface of the package. The balls are made of fusible or non-fusible material, for example a tin-lead mixture. In a known manner, such an array of balls makes it possible to produce the electrical contact for the various connection points of the package with the printed circuit on which the package is mounted, and ensures the assembling of the package on the printed circuit. For this purpose, the printed circuit carries metallic impressions in an arrangement identical to the arrangement of the balls. The balls and the impressions are placed opposite one another and the set comprising the package and the printed circuit is heated so as to bring about the melting of a brazing alloy serving to fix the package onto the printed circuit, and possibly to melt the balls, depending on their composition.

Like any electronic component in general, and any microwave component in particular, a microwave package needs to be characterized, notably for the design and/or the modeling of electronic circuits integrating such a microwave package.

According to a first solution, the characteristics of a microwave package are determined in the following manner. In a first step, a model for simulating the characteristics of the environment is determined, for example in the form of an array of parameters S. In a second step, a vector network analyser is used to measure the characteristics of the package in its environment, for example a test platform linked to the vector network analyser by coaxial cables. The characteristics of the package in its environment are for example modeled in the form of an array of parameters S. On the basis of the two arrays of parameters S, the array of parameters S of the package alone is deduced therefrom in a third step by deducting by calculation the array of parameters S of the environment from the array of parameters S of the package measured in its environment. This determination of the characteristics of a microwave package exhibits several drawbacks. A first drawback results from the fact that the characteristics of the package alone are deduced jointly on the basis of a model and of a measurement, thus necessitating the modeling of the environment in addition to the measurement of the package in its environment. A second drawback is that the environment may comprise elements that are difficult to model such as microwave connectors and non-coaxial transmission media. The interface between the package and the environment may also be difficult to model. Such is notably the case for packages of BGA type. Consequently, the modeling of the environment may be inaccurate, thus falsifying the deduced characteristics of the microwave package.

According to a second solution, the characteristics of the environment are no longer simulated but determined by a calibration method consisting essentially in measuring the test environment in the presence of various standard patterns disposed successively on a test platform and in deducing therefrom the characteristics of the test environment alone. This method of calibration is called TRL calibration. The standard patterns comprise a pattern called a Thru pattern, a pattern called a Reflect pattern and one or more patterns called Line patterns. According to TRL calibration, the test platform consists of two detachable parts each supporting a microstrip line connected to a coaxial cable connector. The two parts may be joined so as to link the free ends of the microstrip lines. This configuration allows direct passage of a microwave signal between the two parts and gives its name to the Thru pattern. Alternatively, the Thru pattern is embodied by a relatively short microstrip line inserted between the two parts. The Reflect pattern is obtained either by simply separating the two parts of the test platform, or by producing a short-circuit at the free ends of the microstrip lines. In both cases, the microwave signal is reflected at the free ends of the microstrip lines. The Line pattern is embodied by a microstrip line of length greater than that of the Thru pattern. Knowing the arrays of parameters S for the various patterns and the electrical length of the microstrip lines of the Thru and Line patterns, generally obtained by simulation, it is possible to deduce the characteristics of the test platform. A microwave package can then be characterized by connecting it to the free ends of the microstrip lines. For a more expanded presentation of TRL calibration and its mathematical model, reference may be made notably to Engen, G. F., Hoer C. A., “Thru-Reflect-Line: An Improved Technique for Calibrating the Dual Six-Port Automatic Network Analyzer”, IEEE Trans. Microwave Theory and Techniques, December 1979. However, this solution suffers from several drawbacks. First of all, the configuration of the test platform is modified in the course of the various measurements, thereby modifying its characteristics. Moreover, the connection between the microstrip lines of the test platform and the microwave feeds of the package is different from the connection between these microstrip lines and the standard patterns. These two observations show on the one hand that TRL calibration introduces calibration errors, and on the other hand that it is not suited to the testing of microwave packages.

An aim of the invention is notably to alleviate all or some of the aforementioned drawbacks. For this purpose, the subject of the invention is a method for calibrating a test platform able to receive a microwave package, characterized in that it comprises the following steps:

determining a first array of parameters S, a first microwave package whose microwave feeds are linked by an etched line of length L_{Thru} being connected to the test platform;

determining a second array of parameters S, a second microwave package whose microwave feeds are short-circuited being connected to the test platform;

determining a third array of parameters S, a third microwave package whose microwave feeds are linked by an etched line of length L_{Line} greater than the length L_{Thru} being connected to the test platform;

a step of determining, on the basis of the first, second and third arrays of parameters S, the characteristics of the test platform.

According to a particular embodiment, the microwave package to be tested comprises a microwave component linked to two microwave feeds, the microwave feeds of the first, second and third microwave packages being identical to the microwave feeds of the microwave package to be tested.

According to a particular embodiment, the microwave packages comprise a ball grid array interface.

According to a particular embodiment, the electrical connection between the microwave packages and the test platform is ensured by pressure.

The subject of the invention is also a set of microwave standard packages able to be connected to a test platform of a microwave package, the said microwave package comprising a microwave component linked to two microwave feeds. According to the invention, the set of standard packages comprises:

a first microwave package whose microwave feeds are linked by an etched line of length L_{Thru},

a second microwave package whose microwave feeds are short-circuited,

a third microwave package whose microwave feeds are linked by an etched line of length L_{Line} greater than the length L_{Thru},

the microwave feeds of the first, second and third microwave packages being identical to the microwave feeds of the microwave package to be tested.

According to a particular embodiment, the microwave packages comprise a ball grid array interface.

The invention relies notably on the fact that the test platform is used at one and the same time to receive the standard packages serving to characterize it and the microwave packages to be measured. The advantage of the invention is notably that it makes it possible to measure the characteristics of the package at the level of its interface with the test platform. These characteristics can thereafter be utilized in a simulator to simulate the behaviour of the package in a different environment from that in which it was measured.

The subject of the invention is further a method for determining an electrical length L_{C} of an etched line linking two microwave feeds of a microwave standard package, the microwave feeds of the standard package being able to be connected to a first and to a second internal interface of a test platform, the test platform comprising a first microwave line between a first external interface and the first internal interface and a second microwave line between a second external interface and the second internal interface. The method according to the invention comprises the following steps:

determining a first electrical length of the first microwave line of the test platform;

determining a second electrical length of the second microwave line of the test platform;

determining a third electrical length corresponding to the electrical length between the external interfaces of the test platform and including the electrical length of the etched line linking the two microwave feeds of the standard package;

deducing from the first, second and third electrical lengths, the electrical length of the etched line.

According to a particular embodiment, the determination of the first electrical length comprises the following sub-steps:

determining an electrical length between a measurement instrument and the first external interface of the test platform;

determining an electrical length between the measurement instrument and the first internal interface of the test platform;

deducing from the electrical lengths between, on the one hand, the measurement instrument and the first external interface of the test platform and, on the other hand, the measurement instrument and the first internal interface of the test platform, the first electrical length.

According to a particular embodiment, the determination of the second electrical length comprises the following sub-steps:

determining an electrical length between a measurement instrument and the second external interface of the test platform;

determining an electrical length between the measurement instrument and the second internal interface of the test platform;

deducing from the electrical lengths between, on the one hand, the measurement instrument and the second external interface of the test platform and, on the other hand, the measurement instrument and the second internal interface of the test platform, the second electrical length.

According to a particular embodiment, the determination of the electrical length between the measurement instrument and an external interface of the test platform comprises a step consisting in disposing a reflecting pattern at that end of a coaxial cable that is to be connected to the said external interface of the test platform.

According to a particular embodiment, the determination of the electrical length between the measurement instrument and an internal interface of the test platform comprises a step consisting in connecting to the internal interfaces of the test platform a microwave package whose microwave feeds are short-circuited.

According to a particular embodiment, the determination of the third electrical length comprises the following sub-steps:

determining an electrical length between a measurement instrument and the second external interface of the test platform, the said length including the electrical length of the etched line;

determining an electrical length between the measurement instrument and the first external interface of the test platform;

deducing from the electrical length between the measurement instrument and the second external interface of the test platform and from the electrical length between the measurement instrument and the first external interface of the test platform, the third electrical length.

This method exhibits the advantage of allowing precise determination of the electrical length of the etched line. This is notably due to the fact that the electrical length of the etched line is obtained by measurement and not by simulation.

The invention will be better understood and other advantages will become apparent on reading the detailed description of an embodiment given by way of example, said description offered in relation to appended drawings in which:

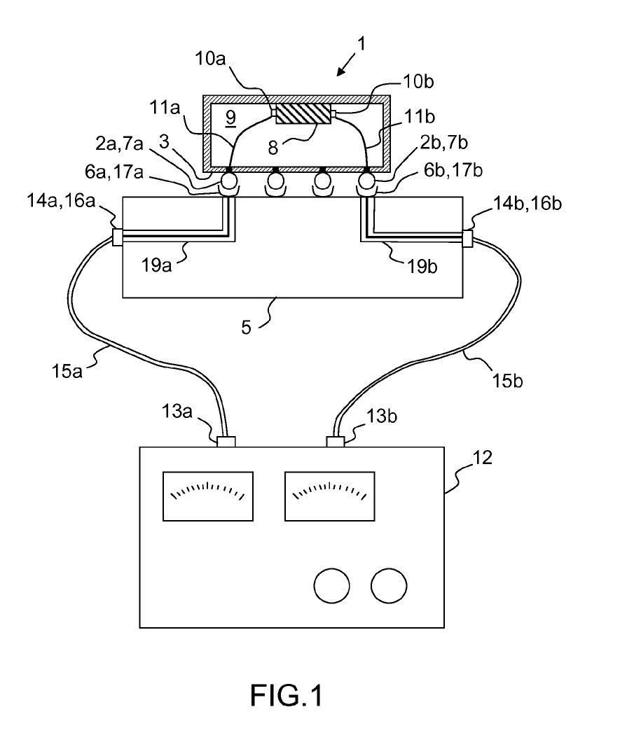

FIG. 1 represents a microwave package to be tested and its test environment;

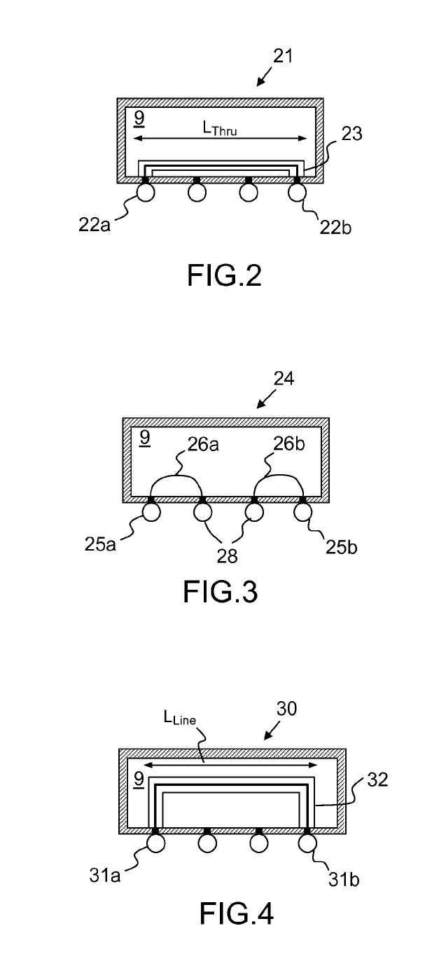

FIG. 2 represents a first microwave standard package;

FIG. 3 represents a second microwave standard package;

FIG. 4 represents a third microwave standard package;

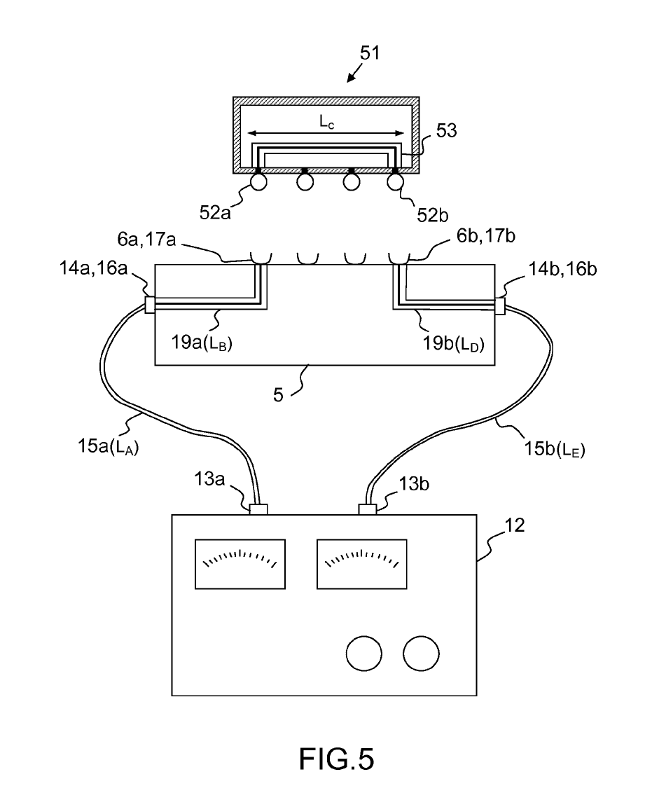

FIG. 5 represents a microwave standard package for which it is sought to determine an electrical length of an etched line and its test environment.

FIG. 1 schematically represents a microwave package 1 for which it is sought to determine the characteristics in its test environment. These characteristics are for example modeled in the form of an array of parameters S. The package 1 is for example a ball grid array package or BGA package. The subsequent description is given while considering a BGA package, however, any type of package, for example a pin grid array package or a land grid array package, may be considered without departing from the scope of the invention. The package 1 comprises balls bearing the generic reference 2 and arranged on a face 3 of the package 1 so as to form an array of balls. This array of balls forms an electrical interface with a test platform 5 and in particular with conducting impressions produced on the test platform 5 and bearing the generic reference 6. Two of the balls 2, bearing the references 2a, 2b, can in particular be used to conduct a microwave signal, notably test microwave signals. These balls 2a and 2b form microwave feeds 7a and 7b of the package 1 and are in contact with the test platform 5 by way of conducting impressions 6a and 6b. The other balls 2 of the package 1 are generally linked to an earth plane, for example the earth plane of the test platform 5, by way of the conducting impressions 6. The microwave package 1 can comprise a microwave component 8 encapsulated in a cavity 9 of the package 1. The microwave component 8 comprises for example two ports, an input port 10a and an output port 10b. Each port 10a, 10b may be linked to the microwave feeds 7a, 7b, for example by way of connection wires 11a, 11b connected to microwave lines themselves in contact with the balls 2a and 2b. The test platform 5 is linked to a measurement instrument 12, for example a vector network analyser, making it possible to determine microwave characteristics between two ports 13a and 13b of the measurement instrument 12. The test platform 5 can comprise connectors 14a and 14b making it possible to link it to the ports 13a and 13b respectively, for example by way of coaxial cables 15a and 15b. The connectors 14a and 14b respectively form a first and a second external interface 16a, 16b of the test platform 5. Likewise, the conducting impressions 6a and 6b respectively form a first and a second internal interface 17a, 17b. The test platform 5 also comprises a first microwave line 19a between the first external interface 16a and the first internal interface 17a and a second microwave line 19b between the second external interface 16b and the second internal interface 17b. The first and second microwave lines 19a, 19b are for example microstrip lines, triplate lines or a combination of microstrip and triplate lines. Triplate lines are also known in the literature by the name “striplines”. A microwave signal can thus travel between the ports 13a and 13b of the measurement instrument 12 by passing successively through a coaxial cable 15a, the connector 14a, the first microwave line 19a, the conducting impression 6a, the ball 2a, the connection wire 11a, the microwave component 8, the connection wire 11b, the ball 2b, the conducting impression 6b, the second microwave line 19b, the connector 14b and the coaxial cable 15b. A microwave signal can quite obviously travel from the port 13b to the port 13a by following the reverse path.

According to the calibration method of the invention the conventional Thru, Reflect and Line standard patterns are replaced by microwave standard packages fulfilling similar functions, the test platform 5 being adapted accordingly, as described hereinabove. A first microwave package, called a Thru package 21, is represented in FIG. 2. It comprises microwave feeds 22a and 22b and an etched line 23 of length L_{Thru} linking the microwave feeds 22a and 22b. A second microwave package, called a Reflect package 24, is represented in FIG. 3. It also comprises microwave feeds 25a and 25b. Nevertheless, these feeds 25a and 25b are short-circuited. The short-circuits are for example produced by connection wires 26a and 26b linking the microwave feeds 25a and 25b to an earth plane, for example balls 28 of the Reflect package 24. The short-circuits can also be produced by removing the resist between the microwave feeds 25a and 25b and the earth plane to which the earth balls 28 are linked, thus putting the microwave feeds 25a and 25b into contact with the earth plane. A third microwave package, called a Line package 30, is represented in FIG. 4. It comprises microwave feeds 31a and 31b and an etched line 32 of length L_{Line} linking the microwave feeds 31a and 31b. The length L_{Line} is generally greater than the length L_{Thru}. The difference in length between L_{Thru} and L_{Line} is dictated by the frequency band in which the microwave package 1 operates. According to the invention, the method of calibrating the test platform 5 comprises the following steps:

determining a first array of parameters S, the Thru package 21 being connected to the test platform 5;

determining a second array of parameters S, the Reflect package 24 being connected to the test platform 5;

determining a third array of parameters S, the Line package 30 being connected to the test platform;

determining, on the basis of the first, second and third arrays of parameters S, the characteristics of the test platform 5.

“Connection of a package 21, 24 or 30 to the test platform 5” should be understood as meaning electrical contact between, on the one hand, the first internal interface 17a of the test platform 5 and one of the microwave feeds 22a, 25a or 31a of the packages 21, 24 and 30, and, on the other hand, the second internal interface 17b of the test platform 5 and one of the microwave feeds 22b, 25b or 31b.

The use of Thru 21, Reflect 24 and Line 30 packages makes it possible to retain the same electrical interface between each of the packages and the test platform 5. In particular, the internal interfaces 17a and 17b of the test platform 5 and the microwave feeds 22a, 22b, 25a, 25b, 31a and 31b may be identical for each of the packages 21, 24 and 30. According to a particular embodiment, the microwave feeds 22a, 22b, 25a, 25b, 31a and 31b are respectively identical to the microwave feeds 7a and 7b of the package 1 to be tested. In particular, the microwave feeds 22a, 25a, 31a on the one hand and 22b, 25b, 31b on the other hand can respectively be formed by the balls 2a and 2b. Stated otherwise, the packages 21, 24 and 30 comprise the same ball grid array interface as the microwave package 1. The internal interfaces 17a and 17b of the test platform 5 then comprise the conducting impressions 6a and 6b.

According to a particularly advantageous embodiment, the Thru 21, Reflect 24 and Line 30 packages are produced on the basis of the same package model as the package 1 to be tested. Consequently, the dimensions of the packages 1, 21, 24 and 30 and their microwave feeds 7a, 7b, 22a, 22b, 25a, 25b, 31a and 31b may be strictly identical. Only the microwave component 8 or the pattern inside the packages 21, 24 and 30, stated otherwise the etched lines 23 and 32 and the short-circuits of the microwave feeds 25a and 25b, differ according to the packages.

According to a particular embodiment, the electrical connection between the packages 1, 21, 24 and 30 and the test platform 5 is ensured by pressure. This pressure is adapted so as to ensure electrical contact between each ball 2 and the corresponding conducting impression 6 without however significantly deforming the balls 2 or the conducting impressions 6. According to another embodiment, the electrical connection between the packages 1, 21, 24 and 30 and the test platform 5 is ensured via an intermediate patch of elastic material, for example described in patent application FR 2 906 890. This intermediate patch makes it possible to ensure the continuity of the microwave signal without impairing the ball grid array interface of the packages 1, 21, 24 and 30. The said packages can then be reused.

The calibration method according to the invention notably exhibits the advantage that the characteristics of the test platform 5 may be reused for several tests of microwave packages 1, insofar as these packages 1 comprise the same ball grid array interface as that of the standard packages 21, 24 and 30. Furthermore, the calibration method is particularly reliable on account of the fact that the characteristics of the test platform 5 inherently include the characteristics of its interface with the various packages 1, 21, 24, 30. Consequently, the characteristics of a microwave package 1 to be tested may be determined at the level of its microwave feeds 7a and 7b. These characteristics can thereafter be utilized in a simulator so as to simulate the behaviour of the package 1 in a different environment from that in which it was measured.

The precision of the determination of the characteristics of the various packages 1, 21, 24, 30 in their test environment depends notably on the precise knowledge of the electrical length of the etched lines 23 and 32 of the Thru 21 and Line 30 packages. For this purpose, the invention also proposes a method of determining an electrical length of an etched line of a microwave package. The invention is notably, but not exclusively, applied to the determination of the electrical length of the etched lines 23 and 32. This method of determination is now described with reference to FIG. 5.

FIG. 5 schematically represents a microwave package 51 in the test environment of FIG. 1. In particular, the test environment comprises the test platform 5 linked to the measurement instrument 12 by the coaxial cables 15a and 15b. Within the framework of the invention, the microwave package 51 corresponds either to the Thru package 21, or to the Reflect package 24, or else to the Line package 30. However, the general case is considered of a microwave package 51 comprising two microwave feeds 52a and 52b able to be connected to the first and to the second internal interfaces 17a, 17b of the test platform 5 and an etched line 53 of electrical length L_{C} linking the microwave feeds 52a and 52b. The electrical length of a line may be defined as the ratio of its physical length to its velocity factor. In FIG. 5, the electrical length L_{C} corresponds substantially to the physical length of the etched line 53. However, this representation is aimed solely at facilitating understanding and does not imply that the electrical length L_{C} and the physical length of the etched line 53 actually correspond. According to the invention, the method comprises the following steps:

determining a first electrical length L_{B} of the first microwave line 19a of the test platform 5;

determining a second electrical length L_{D} of the second microwave line 19b of the test platform 5;

determining a third electrical length L_{BCD} corresponding to the electrical length between the external interfaces 16a and 16b of the test platform 5 and including the electrical length L_{C} of the etched line 53. Stated otherwise, the electrical length L_{BCD} corresponds to the sum of the electrical lengths L_{B}, L_{C} and L_{D};

deducing from the first, second and third electrical lengths L_{B}, L_{D} and L_{BCD}, the electrical length L_{C} of the etched line 53.

According to a particular embodiment, the determination of the first electrical length L_{B} comprises the following sub-steps:

determining an electrical length L_{A} between the measurement instrument 12 and the first external interface 16a of the test platform 5;

determining an electrical length L_{AB} between the measurement instrument 12 and the first internal interface 17a of the test platform 5;

deducing from the electrical lengths L_{A} and L_{AB} between, on the one hand, the measurement instrument 12 and the first external interface 16a of the test platform 5 and, on the other hand, the measurement instrument 12 and the first internal interface 17a of the test platform 5, the first electrical length L_{B}.

According to a particular embodiment, the determination of the second electrical length L_{D} comprises the following sub-steps:

determining an electrical length L_{E} between the measurement instrument 12 and the second external interface 16b of the test platform 5;

determining an electrical length L_{DE} between the measurement instrument 12 and the second internal interface 17b of the test platform 5;

deducing from the electrical lengths L_{E} and L_{DE} between, on the one hand, the measurement instrument 12 and the second external interface 16b of the test platform 5 and, on the other hand, the measurement instrument 12 and the second internal interface 17b of the test platform 5, the second electrical length L_{D}.

According to a particular embodiment, the determination of the electrical length L_{A} or L_{E} between the measurement instrument 12 and one of the external interfaces 16a or 16b of the test platform 5 comprises a step consisting in disposing a reflecting pattern at that end of the coaxial cable 15a or 15b that is to be connected to the said external interface 16a or 16b of the test platform 5. The reflecting pattern corresponds for example to a short-circuit or to an open circuit. Thus, an incident microwave signal is reflected at the end of the coaxial cable 15a or 15b and returns to the measurement instrument 12.

According to a particular embodiment, the determination of the electrical length L_{AB} or L_{DE} between the measurement instrument 12 and one of the internal interfaces 17a or 17b of the test platform 5 comprises a step consisting in connecting to the internal interfaces 17a and 17b of the test platform 5 a microwave package whose microwave feeds are short-circuited. In one embodiment, this microwave package is the Reflect package 24. This embodiment makes it possible to employ the same package model as the Thru 21 and Line 30 packages. In particular, the electrical interfaces with the test platform 5 are identical for the various packages.

According to a particular embodiment, the determination of the third electrical length L_{BCD} comprises the following sub-steps:

determining an electrical length L_{ABCD} between the measurement instrument 12 and the second external interface 16b of the test platform 5, the said length including the electrical length L_{C} of the etched line 53;

determining the electrical length L_{A} between the measurement instrument 12 and the first external interface 16a of the test platform 5;

deducing from the electrical length L_{ABCD} between the measurement instrument 12 and the second external interface 16b and from the electrical length L_{A} between the measurement instrument 12 and the first external interface 16a of the test platform 5, the third electrical length L_{BCD}.

According to a particular embodiment, the determination of an electrical length L_{A}, L_{AB}, L_{ABCD}, L_{E} or L_{DE} between the measurement instrument 12 and one of the interfaces 16a, 16b, 17a or 17b of the test platform comprises the measurement of an incident microwave signal, the measurement of a microwave signal that is reflected at the level of one of the interfaces 16a, 16b, 17a or 17b, and the determination of the ratio between the incident microwave signal and the reflected microwave signal. This ratio, called the reflection factor, makes it possible notably to determine a phase shift between the incident and reflected microwave signals. On the basis of this phase shift and the knowledge of a speed of propagation of the incident and reflected microwave signals between the measurement instrument 12 and one of the interfaces 16a, 16b, 17a or 17b, it is possible to determine the electrical length L_{A}, L_{AB}, L_{ABCD}, L_{E} or L_{DE}.

1. Method for calibrating a test platform (5) able to receive a microwave package (1), characterized in that it comprises the following steps:
determining a first array of parameters S, a first microwave package (21) whose microwave feeds (22a, 22b) are linked by an etched line (23) of length L_{Thru} being connected to the test platform (5);
determining a second array of parameters S, a second microwave package (24) whose microwave feeds (25a, 25b) are short-circuited being connected to the test platform (5);
determining a third array of parameters S, a third microwave package (30) whose microwave feeds (31a, 31b) are linked by an etched line (32) of length L_{Line} greater than the length L_{Thru} being connected to the test platform (5);
determining, on the basis of the first, second and third arrays of parameters S, the characteristics of the test platform (5).

2. Method according to claim 1, characterized in that the microwave package (1) to be tested comprises a microwave component (8) linked to two microwave feeds (7a, 7b), the microwave feeds (22a, 22b, 25a, 25b, 31a, 31b) of the first, second and third microwave packages (21, 24, 30) being identical to the microwave feeds (7a, 7b) of the microwave package (1) to be tested.

3. Method according to one of claim 1 or 2, characterized in that the microwave packages (1, 21, 24, 30) comprise a ball grid array interface.

4. Method according to one of the preceding claims, characterized in that the electrical connection between the microwave packages (1, 21, 24, 30) and the test platform (5) is ensured by pressure.

5. Set of microwave standard packages (21, 24, 30) able to be connected to a test platform (5) of a microwave package (1), the said microwave package (1) comprising a microwave component (8) linked to two microwave feeds (7a, 7b), the set being characterized in that it comprises:
a first microwave package (21) whose microwave feeds (22a, 22b) are linked by an etched line (23) of length L_{Thru},
a second microwave package (24) whose microwave feeds (25a, 25b) are short-circuited,
a third microwave package (30) whose microwave feeds (31a, 31b) are linked by an etched line (32) of length L_{Line} greater than the length L_{Thru},
the microwave feeds (22a, 22b, 25a, 25b, 31a, 31b) of the first, second and third microwave packages (21, 24, 30) being identical to the microwave feeds (7a, 7b) of the microwave package (1) to be tested.

6. Set according to claim 5, characterized in that the microwave packages (1, 21, 24, 30) comprise a ball grid array interface.

7. Method for determining an electrical length L_{C} of an etched line (53) linking two microwave feeds (52a, 52b) of a microwave standard package (51), the microwave feeds (52a, 52b) of the standard package (51) being able to be connected to a first and to a second internal interface (17a, 17b) of a test platform (5), the test platform (5) comprising a first microwave line (19a) between a first external interface (16a) and the first internal interface (17a) and a second microwave line (19b) between a second external interface (16b) and the second internal interface (17b), the method being characterized in that it comprises the following steps:
determining a first electrical length (L_{B}) of the first microwave line (19a) of the test platform (5);
determining a second electrical length (L_{D}) of the second microwave line (19b) of the test platform (5);
determining a third electrical length (L_{BCD}) corresponding to the electrical length between the external interfaces (16a, 16b) of the test platform (5) and including the electrical length (L_{C}) of the etched line (53) linking the two microwave feeds (52a, 52b) of the standard package (51);
deducing from the first, second and third electrical lengths (L_{B}, L_{D}, L_{BCD}), the electrical length (L_{C}) of the etched line (53).

8. Method according to claim 7, characterized in that the determination of the first electrical length (L_{B}) comprises the following sub-steps:
determining an electrical length (L_{A}) between a measurement instrument (12) and the first external interface (16a) of the test platform (5);
determining an electrical length (L_{AB}) between the measurement instrument (12) and the first internal interface (17a) of the test platform (5);
deducing from the electrical lengths (L_{A}, L_{AB}) between, on the one hand, the measurement instrument (12) and the first external interface (16a) of the test platform (5) and, on the other hand, the measurement instrument (12) and the first internal interface (17a) of the test platform (5), the first electrical length (L_{B}).

9. Method according to one of claim 7 or 8, characterized in that the determination of the second electrical length (L_{D}) comprises the following sub-steps:
determining an electrical length (L_{E}) between a measurement instrument (12) and the second external interface (16b) of the test platform (5);
determining an electrical length (L_{DE}) between the measurement instrument (12) and the second internal interface (17b) of the test platform (5);
deducing from the electrical lengths (L_{E}, L_{DE}) between, on the one hand, the measurement instrument (12) and the second external interface (16b) of the test platform (5) and, on the other hand, the measurement instrument (12) and the second internal interface (17b) of the test platform (5), the second electrical length (L_{D}).

10. Method according to one of claim 8 or 9, characterized in that the determination of the electrical length (L_{A}, L_{E}) between the measurement instrument (12) and an external interface (16a, 16b) of the test platform (5) comprises a step consisting in disposing a reflecting pattern at that end of a coaxial cable (15a, 15b) that is to be connected to the said external interface (16a, 16b) of the test platform (5).

11. Method according to one of claims 8 to 10, characterized in that the determination of the electrical length (L_{AB}, L_{DE}) between the measurement instrument (12) and an internal interface (17a, 17b) of the test platform (5) comprises a step consisting in connecting to the internal interfaces (17a, 17b) of the test platform (5) a microwave package (24) whose microwave feeds (25a, 25b) are short-circuited.

12. Method according to one of claims 7 to 11, characterized in that the determination of the third electrical length (L_{BCD}) comprises the following sub-steps:
determining an electrical length (L_{ABCD}) between a measurement instrument (12) and the second external interface (16b) of the test platform (5), the said length including the electrical length (L_{C}) of the etched line (53);
determining an electrical length (L_{A}) between the measurement instrument (12) and the first external interface (16a) of the test platform (5);
deducing from the electrical length (L_{ABCD}) between the measurement instrument (12) and the second external interface (16b) of the test platform (5) and from the electrical length (L_{A}) between the measurement instrument (12) and the first external interface (16a) of the test platform (5), the third electrical length (L_{BCD}).
